(19) United States
(12) Patent Application Publication
(10) Pub. No.: US 2007/0226572 A1
(43) Pub. Date: Sep. 27, 2007

(54) Soft error rate analysis system

(76) Inventors: Ming Zhang, Folsom, CA (US); Naresh R. Shanbhag, Champaign, IL (US)

Correspondence Address: BRINKS HOFER GILSON & LIONE, P.O. BOX 10395, CHICAGO, IL, 60610, US

(21) Appl. No.: 11/592,712

(22) Filed: Nov. 2, 2006

Related U.S. Application Data
(60) Provisional application No. 60/734,408, filed on Nov. 7, 2005.

(51) Int. Cl. G01R 31/28; G06F 11/00

(52) U.S. Cl. 714/742

(57) ABSTRACT

A method for improving reliability of an electronic system by evaluating a soft error rate is disclosed. A gate-level representation of the electronic system is converted to a graph, the graph having vertices and edges that correspond to nodes and gates of the electronic system. Input vectors are generated, which correspond to inputs supplied to the electronic system. A soft error rate for the electronic system is evaluated during a simulated operation of the electronic system, and the evaluated soft error rate is correlated to a set of parameters used to configure the electronic system.

### PRIORITY CLAIM

This application claims the benefit of priority of U.S. Provisional Patent Application No. 60/734,408, “Method for Improving Reliability of an Electronic System by Evaluating a Soft Error Rate,” filed Nov. 7, 2005, the contents of which are incorporated by reference herein.

### FIELD OF INVENTION

The present invention relates, in general, to soft errors in circuitry and, more particularly, to a system for analyzing a soft error rate of combinational and sequential circuits.

### BACKGROUND

Soft errors are transient faults caused by external radiation, mainly cosmic rays, that affect logic states of integrated circuits (IC) and memories. The constantly decreasing size of microelectronic circuits and devices together with cutback of voltage supply reduces the circuits' noise margin. This leads to increased vulnerability of the logic circuits to soft errors. A soft error arises when a sensitive part of a semiconductor circuit is hit by high-energy neutrons, which are present in cosmic radiation, or alpha particles, which originate from impurities in the packaging materials. The latter is easier to prevent by changing the packaging material. On the other hand, the neutrons are almost unstoppable and they can even penetrate thick concrete walls. There are several different approaches and solutions for decreasing soft errors in the logic circuits.

Soft errors caused by particle hits are a serious problem for modern static random access memory (SRAM) designs due to reduced feature size and supply voltage. An empirical soft error rate (SER) model has been proposed for SRAMs, which predicts SER from critical charge Q_{crit}, drain area, neutron flux and other empirical parameters. Researchers have shown that the soft error rate (SER) in logic is posing a threat now and may increase by orders of magnitude within the next few years.

Modeling and analysis of SER in logic is an inherently more complex problem than in memory. A single Q_{crit} value may not be sufficient to describe SER in logic circuits, as both storage nodes (e.g., D-flip-flops (DFFs) or registers) and the combinational circuit nodes are susceptible to particle hits. A single event transient (SET) generated by a particle hit at a combinational circuit node may experience electrical, timing, and logical maskings before reaching the next pipeline stage and cause a bit error. Electrical masking is a strong function of the sizing of gates in the logic chain; timing masking mainly depends on the D-flip-flop design; logical masking is mostly determined by the input vectors. The above mentioned masking mechanisms pose a major challenge for modeling SER in combinational logic. A wide body of research is available that addresses the combinational logic SER problem from different perspectives.

Tools such as soft-error Monte Carlo modeling (SEMM) employed conventionally provide an appreciable level of accuracy that can be achieved by simulations but is quite expensive because time-consuming Monte Carlo simulations are used. Another tool for a simulation of single event upset (SEU) transients (SITA) uses parameterized closed form expressions to represent the responses of each gate to a single event transient (SET). The generation, propagation, and capture of the SET are modeled without running time-consuming circuit level simulations, and hence the speed of tool is greatly improved. However, a simulation of single event upset (SEU) transients (SITA) does require a database of parameters to fit the analytical expressions. The complexity of such analytical expressions is expected to increase dramatically for newer fabrication processes as a result of increasing complexity of the device models.

Another tool uses a gate-level timing simulator to model SETs and a zero delay fault simulator to track bit errors. Loss in accuracy due to the nature of the logic level simulator has been noted. Other examples of logic level simulation are not computationally intensive, but the loss in accuracy is inevitable due to the simplifying assumptions made such as the “linear ramp glitch” assumption and “effective noise window” assumption.

Another tool, called “DYNAMO,” utilizes an efficient dynamic mixed-mode simulation approach, where the various portions of the circuit may switch between different levels of abstraction during the simulation. Time consuming circuit level simulations are used only when deemed necessary by the tool. This approach provides better accuracy than the logic level tools at the price of longer run times. Another tool called “SEUTool” analyzes soft error phenomenon in combinational and sequential CMOS logic circuits. This technique can identify problematic regions within the circuit and predict the overall circuit reliability. However, the effect of re-convergent fan-out on the SER of a combinational logic is not accounted for.

SEUPER FAST is another tool at an even higher level of abstraction, which is a mathematical model rather than a simulator. SEUPER FAST endeavors to reduce execution time by avoiding simulations at both the circuit and logic level. However, the inaccuracy in predicting SER for combinational logic can be as high as 30%. Such high level of inaccuracy is caused by its simplified treatment of transients. For example, it does not consider transient pulse shapes, treating all transients as square pulses of a fixed width. It also ignores pulse attenuation and simply assigns zero propagation probability to all generated pulses with widths narrower than the minimum set-up and hold time of the receiving DFF. Prior work has also attempted the model of SER of combinational logic from a system perspective. These approaches also use simplifying assumptions such as the concept of “vulnerability window.” These simplifying assumptions may limit the accuracy, although they are justified by speed-ups required to analyze large designs such as a microprocessor. Most of the discussed solutions are either too expensive or create too much overhead.

### BRIEF SUMMARY

A method that improves a reliability of an electronic system by evaluating a soft error rate is disclosed. A gate-level representation of the electronic system to a graph is generated in the method. The graph has vertices and edges that correspond to nodes and gates of the electronic system. Input vectors are generated, which correspond to inputs supplied to the electronic system, evaluates the soft error rate during a simulated operation of the electronic system, and the evaluated soft error rate is correlated to a set of parameters used to configure the electronic system. The set of parameters are used to configure the nodes and the gates of the electronic system with a maximized reliability based on the evaluated soft error rate.

An electronic system including gates or storage nodes is disclosed, where the gates or the storage nodes are arranged based on a process that improves a reliability of the electronic system. The process includes converting a gate-level representation of the electronic system to a graph, the graph having a vertex and an edge that correspond to nodes and gates of the electronic system; generating input vectors, the input vectors corresponding to inputs supplied to the electronic system; evaluating a soft error rate during a simulated operation of the electronic system; and correlating the evaluated soft error rate to a set of parameters stored in a computer-readable medium, where the set of parameters are used to configure the nodes and the gates of the electronic system with a maximized reliability based on the evaluated soft error rate.

A method for designing an electronic system with an improved reliability is disclosed. The method includes converting a gate-level representation of the electronic system to a graph, the graph having a vertex and an edge that correspond to nodes and gates of the electronic system, where the electronic system includes at least one of a plurality of logic gates or a plurality of storage elements; generating input vectors, the input vectors corresponding to inputs supplied to the electronic system; evaluating a soft error rate during a simulated operation of the electronic system; correlating the evaluated soft error rate to a set of parameters related to the electronic system; and arranging the at least one logic gate or the at least one storage element based on the set of parameters related to the electronic system.

Other systems, methods, features and advantages of the invention will be, or will become, apparent to one with skill in the art upon examination of the following figures and detailed description. It is intended that all such additional systems, methods, features and advantages be included within this description, be within the scope of the invention, and be protected by the following claims.

### BRIEF DESCRIPTION OF THE DRAWINGS

The invention can be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIGS. 1a-d illustrate block diagrams of a combinational circuit with potential locations of particle hits and enlarged views of portions of the circuit.

FIGS. 2 a-b illustrate SET propagations and captures.

FIG. 3 is a block diagram illustrating a simulation setup for the combinational circuit of FIGS. 1a-d

FIGS. 4a-c are plots of the conditional probabilities of a soft error rate.

FIG. 5 is an example block diagram of a system that evaluates an electronic system reliability.

FIG. 6 is a flow chart illustrating a method for evaluating the soft error rate.

FIG. 7 is a block diagram illustrating contributions from internal circuit nodes to the soft error rate.

FIG. 8 is a table illustrating a comparison between the Monte Carlo and the soft error rate analysis methods.

FIG. 9 is a block diagram illustrating a Monte Carlo simulation for a soft error rate analysis verification.

FIG. 10 is graph representing a normalized soft error rate.

FIGS. 11a-d are graphs of the soft error rate as a function of input vectors to the circuit.

FIGS. 12a-d are graphs of the soft error rate evaluated at individual bits of multipliers of various sizes.

FIGS. 13a-d are graphs of the contribution of soft error rate from different memory elements.

FIG. 14 is a graph illustrating a comparison between overall soft error rates and SRAMs.

FIGS. 15a-c are graphs illustrating the soft error rate upper bound.

FIGS. 16a-d are graphs illustrating the soft error rate at individual bits of multipliers of different sizes.

FIG. 17 is graph illustrating the soft error rate scaling factor.

FIG. 18 illustrates a general computer system that may implement a soft error rate analysis.

### DETAILED DESCRIPTION

The present invention is defined by the appended claims. This description summarizes some aspects of the present embodiments and should not be used to limit the claims.

While the present disclosure may be embodied in various forms, there are shown in the drawings and will hereinafter be described some exemplary and non-limiting embodiments, with the understanding that the present disclosure is to be considered an exemplification of the disclosure and is not intended to limit the invention to the specific embodiments illustrated.

In this application, the use of the disjunctive is intended to include the conjunctive. The use of definite or indefinite articles is not intended to indicate cardinality. In particular, a reference to “the” object or “a and an” object is intended to denote also one of a possible plurality of such objects.

The disclosed soft error rate analysis (SERA) method is systematic, efficient, and versatile. The SERA method is systematic in that it builds upon a rigorously derived probabilistic framework, which connects different layers of the soft error phenomenon nearly seamlessly. It outputs an error rate (in terms of number of errors per unit time) for any given circuit based on environmental factors (e.g. particle flux and probability density function of injected charge), circuit structure (e.g. logic topology and DFF circuit design), and usage model (e.g. input vectors). The provided SERA method is efficient as it employs probability theory, circuit simulation, graph theory and fault simulation. Various SERA tasks are divided into groups and handled by different methods. Graph theory and fault simulation are used to analyze the logical masking mechanism for a given circuit as well as to extract logic paths consisting of equivalent inverters. Circuit simulations are then preformed on such selected logic paths to analyze the electrical and timing masking mechanisms. An experimentally verified accurate current pulse model is employed to emulate a particle hit at the device level. By employing this divide-and-conquer approach, a high level of accuracy may be maintained while keeping a low computational complexity.

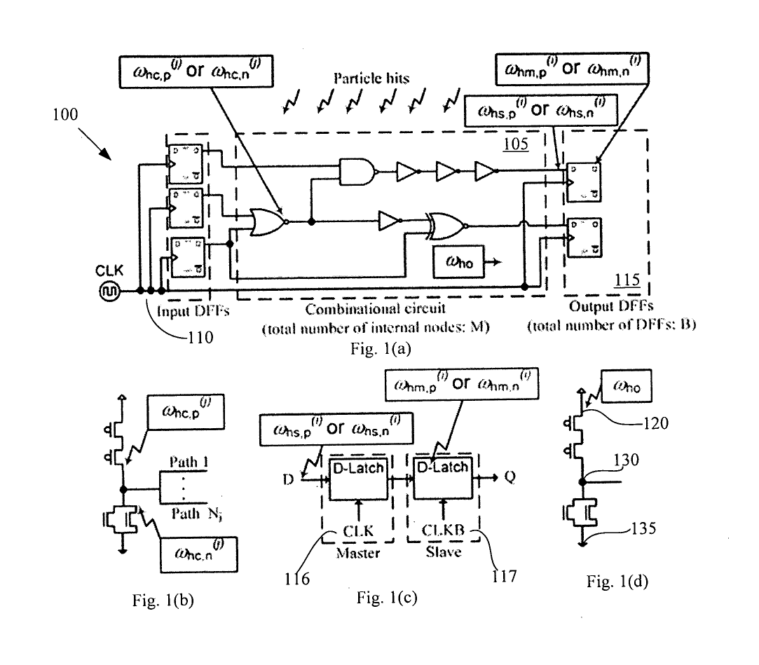

FIG. 1a illustrates a canonical clocked logic circuit (CCLC) 100 composed of a combinational circuit 105 with latched primary inputs 110 and outputs 115. A memory array is a special case of CCLC 100 where only storage elements are present. A chip can then be treated as a network consisting of CCLCs.

A soft error is said to have occurred in the CCLC if a DFF captures the SET generated by a particle hit. The upper bound on the SER (number of soft errors per unit time) of a chip is given by Equation (1):

$${SER}_{chip} \leq {\sum }_{k = 1}^{{N}_{c}} {SER}_{CCLC , k} \qquad Equation ( 1 )$$

where N_{c} is the number of CCLCs on the chip. Equation (1) becomes an equality only if the CCLCs are independent. The SER of a memory array, for example, is the sum of SER for each memory cell. The modeling of various system-level derating mechanisms in an electronic system results in reduction in overall SER. For a modeling of SER in a CCLC 100, the SER of a CCLC 100 is defined as follows in Equation (2):
SER_{CCLC}=R_{PH}·α·P(SE) Equation (2)

where R_{PH} is the particle hit rate, α is the fraction of particle hits that result in charge generation, and P(SE) is the probability of a soft error conditioned on an effective particle hit. The product (R_{PH} α) denotes the rate of effective particle hits. The concept of effective particle hits is an abstraction of several physical processes in which particles interact with the semiconductor substrate to produce bursts of charge.

A rate of effective particle hits may be derived from an empirical model. The hit rate of various particle types such as alpha particles or neutrons, are generally available from experiments. The particle hit rate R_{PH} caused by cosmic ray neutrons, for example, is given by Equation (3):

$${R}_{PH} = {\int }_{{E}_{n , min}}^{{E}_{n , max}} {F}_{n} ( {E}_{n} ) ⅆ {E}_{n} \cdot {A}_{t} \qquad ( 3 )$$

where Fₙ(Eₙ) is the altitude and location-dependent neutron flux defined between neutron energies Eₙₘᵢₙ and E_{n,max}, and Aₜ is the total silicon area of the CCLC.

The probability space over which the probability of a soft error conditioned on an effective particle hit may be estimated. Without loss of generality, one particle hit is assumed to be effective within a clock period resulting in a single event upset (SEU). This assumption is justified by the typically small value of particle flux (total neutron flux at sea level is 56.5 m⁻²s₋₁), small chip area and short clock period. The probability list, probability space, and events of interest are defined as follows: ω^{(ƒ)}_{hc,p} is a generated charge q collected by a p-type drain of a jth circuit node; ω^{(ƒ)}_{hc,n} is a generated charge q collected by an n-type drain of the jth circuit node; ω^{(ƒ)}_{hs,p} is the generated charge q collected by a p-type drain of an ith DFF sample stage; ω⁽ⁱ⁾_{hs,n} is a generated charge q collected by an n-type drain of the ith DFF sample stage; ω⁽ⁱ⁾_{hm,p} is the generated charge collected by a p-type drain of an ith DFF hold stage; ω⁽ⁱ⁾_{hm,n} is a generated charge collected by an n-type drain of the ith DFF hold stage; and ωₕₒ is the generated charge not collected by a circuit node, DFF sample stage, or hold stage. In the above definitions, jε{(1, 2, . . ., M} and iε{1, 2, . . . , B}. Further, the sample space Ωis Ω={ω⁽¹⁾_{hc,p}, ω⁽¹⁾_{hc,n}, . . . , ω^{(M)}_{hc,p}, ω^{(M)}_{hc,n}, ω⁽¹⁾_{hs,p}ω⁽¹⁾_{hs,n}, . . . ,ω^{(B)}_{hs,pω}^{(B)}hs,n, ω⁽¹⁾_{hm,p}, ω⁽¹⁾_{hm,n}, . . . , ω^{(B)}_{hm,p}, ω^{(B)}_{hm,n}, ωₕₒ}. The triple (Ω, B, P) is the probability space, where B is the corresponding σ-field and P is a probability measure.

where A_{c,p}^{(J)},A_{c,n}^{(J)},A_{s,p}⁽ⁱ⁾,A_{s,n}⁽ⁱ⁾,A_{m,p}⁽ⁱ⁾and A_{m,n}⁽ⁱ⁾ are the sensitive p or n-type drain areas of corresponding circuit nodes , respectively.

The events of interest may be defined as: 1) SE(i): soft error at ith output bit; 2) SE: soft error at any output bit; SE=∪ᵢ₌₁^{B} SE^{(i);} 3) HC^{(j)}ₚ={ω^{(j)}_{hc,p}}; P(HC^{(j)}ₚ)=A^{(j)}_{c,p}/Aₜ; 4) HC^{(j)}ₙ={ω^{(j)}_{hc,n}}; P(HC^{(j)}ₙ=A^{(j)}_{c,n}/Aₜ; 5) HS⁽ⁱ⁾_{p={ω}⁽ⁱ⁾_{hs,p}}; P(HS⁽ⁱ⁾ₚ)=A⁽ⁱ⁾_{s,p}/Aₜ; 6) HS⁽ⁱ⁾ₙ={ω⁽ⁱ⁾_{hs,n}; {P(HS⁽ⁱ⁾ₙ)=A⁽ⁱ⁾_{s,n}Aₜ; 7) HM⁽ⁱ⁾ₚ={ω⁽ⁱ⁾_{hm,p}}; P(HM⁽ⁱ⁾_{p)=A}⁽ⁱ⁾_{m,p}/Aₜ; 8) HM⁽ⁱ⁾ₙ={ω⁽ⁱ⁾_{hm,n}}; P(HM⁽ⁱ⁾ₙ)=A⁽ⁱ⁾_{m,n}/Aₜ; 9) HO={ωₕₒ}

Where:

$$\begin{matrix}P ( HO ) = \frac{1}{ {A}_{ t}} [ {A}_{ t} - {\sum }_{j = 1}^{ M} ( {A}_{ c , p}^{( j )} + {A}_{ c , n}^{( j )} ) - \\ {\sum }_{i = 1}^{B} ( {A}_{s , p}^{( i )} + {A}_{s , n}^{( i )} + {A}_{m , p}^{( i )} + {A}_{m , n}^{( i )} ) ]\end{matrix}$$

and A^{(j)}_{c,p}, A^{(j)}_{c,n}, A⁽ⁱ⁾_{s,p}, A⁽ⁱ⁾_{s,n}, A⁽ⁱ⁾_{m,p}, and A⁽ⁱ⁾_{m,n} are the sensitive p- or n-type drain areas of corresponding circuit nodes, respectively.

From the above definitions, Events 1 and 2 are the soft error events of interest and will be further quantified in the succeeding sections. Events 3 to 9 are elemental effective particle hit events. Event 3 and 4 are illustrated in FIG. 1(b). Events 5 to 8 account for the fact that commonly-used master-slave DFFs have two stages: sample 116 and hold 117, both of which are susceptible to particle hits as illustrated in FIG. 1(c). Event 9 is associated with a particle hit occurring at an irrelevant location, e.g., in the substrate far away from a drain node 120 or at the source terminal 130 of a transistor connected to a supply rail 135 as illustrated in FIG. 1(d). Event 9 does not cause soft errors, i.e., P(SE^{(i)/}Ho)=0. The charge released by an incoming particle can be collected by a circuit node only if the particle hit occurs within a sensitive area around the node. This property is quantified by the definitions of probabilities of elemental events as shown above.

The probability of soft error at the ith output bit is derived from the theorem of total probability as follows in Equation (4):

$$\begin{matrix}P ( {SE}^{( i )} ) = {\sum }_{j = 1}^{ M} [ P ( {SE}^{( i )} \vert {HC}_{ p}^{( j )} ) P ( {HC}_{ p}^{( j )} ) + \\ P ( {SE}^{( j )} \vert {HC}_{ n}^{( j )} ) P ( {HC}_{ n}^{( j )} ) ] + \\ {\sum }_{j = 1}^{ B} [ P ( {SE}^{( i )} \vert {HS}_{ p}^{( j )} ) \div P ( {SE}^{( i )} \vert {HS}_{ n}^{( j )} ) \\ P ( {HS}_{ n}^{( j )} ) ] + {\sum }_{j = 1}^{ B} [ P ( {SE}^{( i )} \vert {HM}_{ p}^{( j )} ) \\ P ( {HM}_{ p}^{( j )} ) + P ( {SE}^{( i )} \vert {HM}_{ n}^{( j )} ) P ( {HM}_{ n}^{( j )} ) ]\end{matrix} \qquad Equation ( 4 )$$

As the CMOS gates are unidirectional, an effective particle hit at the sample or hold stage of one DFF may not introduce soft errors in another DFF. Hence, equation (4) above can be simplified as in Equation (5):

$$\begin{matrix}P ( {SE}^{( i )} ) = {\sum }_{j = 1}^{M} [ P ( {SE}^{( i )} \vert {HC}_{p}^{( j )} ) P ( {HC}_{p}^{( j )} ) + \\ P ( {SE}^{( i )} \vert {HC}_{n}^{( j )} ) P ( {HC}_{n}^{( j )} ) ] + \\ P ( {SE}^{( i )} \vert {HS}_{p}^{( i )} ) P ( {HS}_{p}^{( i )} ) + P ( {SE}^{( i )} \vert {HS}_{n}^{( i )} ) \\ P ( {HS}_{n}^{( i )} ) + P ( {SE}^{( i )} \vert {HM}_{p}^{( i )} ) P ( {HM}_{p}^{( i )} ) + \\ P ( {SE}^{( i )} \vert {HM}_{n}^{( i )} ) P ( {HM}_{n}^{( i )} )\end{matrix} \qquad Equation ( 5 )$$

Fan-outs from a particular gate, as illustrated in FIG. 1(b), make it possible for one effective particle hit event to cause soft errors at more than one output bit and hence the following inequality (6) holds:

$${max}_{i} P ( {SE}^{( i )} ) \leq P ( SE ) \leq {\sum }_{i = 1}^{B} P ( {SE}^{( i )} ) \qquad Equation ( 6 )$$

The SERA framework for complex combinational circuits includes the following acts. The conditional probabilities in Equation (5) are extracted from an inverter chain circuit via circuit simulations, and these results are utilized together with graph theory and fault simulation to analyze the SER of complex combinational circuits. A generalized SERA framework that can be employed to analyze other transient noise problems is discussed. The quantities defined in Equations (3) and (1) can be extracted from cosmic ray data and chip layouts. Further, the process to obtain the conditional probabilities appears in Equation (5).

An impact of an effective cosmic ray neutron hit on a circuit node is modeled by a time-dependent pulse current source at a drain node, as follows:

$${I}_{( q , {t}_{PH} )} ( t ) = \{ \begin{matrix}0 , & t < {t}_{PH} \\ \pm \frac{2 q}{τ \sqrt{π}} \sqrt{\frac{t - {t}_{PH}}{τ}} {ⅇ}^{- \frac{t - {t}_{PH}}{τ}} , & t \geq {t}_{PH}\end{matrix} ( 7 ) \qquad Equation ( 7 )$$

where q is the amount of collected charge, t_{PH} is the time instant at which a particle hits the node, and τ is a process technology-dependent time constant. The polarity of the current source is determined by whether the charge is collected by a p or n-type drain, as a drain node can collect only the minority carriers from the substrate or a well. A particle hit occurring at a p-type drain would, for example, induce a current pulse with negative sign in Equation (7), which means positive charge is being injected to the node and the voltage may increase momentarily as a result.

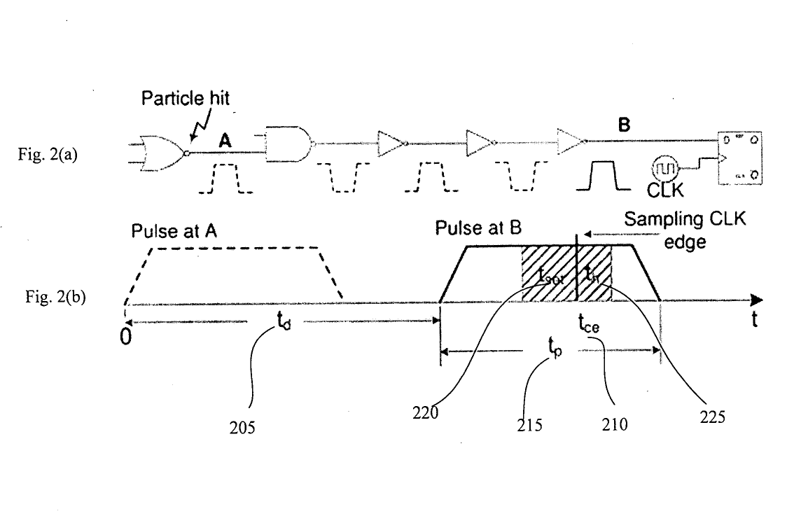

The conditional probabilities in Equation (5) can be determined by applying the current waveform in Equation (7) to various nodes of the circuit in FIG. 1(a). The polarity of the current source together with the logic state of victim node determines whether the logic state is corrupted. If, for example, the logic value of a node is 1 and the current source attached to that node has positive polarity due to a particle hit at a n-type drain, a 1-0-1 SET may occur. A particle hit at a p-type drain will only reinforce the logic state 1. The outputs of DFFs are observed to determine whether the SET will be captured. The sampling clock edge arrival time t_{ce} is defined relative to the instant a particle hit occurs which is assumed to be at time t=0 for convenience as illustrated in FIG. 2. Three conditions need to be satisfied for a soft error to occur: logical masking must not occur; the SET pulse arriving at DFF input B must be wide enough; and the pulse amplitude at DFF input must be large enough.

FIG. 2(a) illustrates an example of Condition 1. Condition 2 is satisfied if the pulse delay t_{d} 205 is close to t_{ce} 210 and if the pulse duration tₚ 215 is comparable to or greater than the sum of DFF setup time tₛₑₜ 220 and hold time tₕ′ 225 as illustrated in FIG. 2(b). Attenuation of a noise pulse when it propagates through cascading gates may cause the violation of Condition 3. The proposed SERA methodology models all the three effects to compute the SER.

The expressions for conditional probabilities corresponding to effective particle hits at p-type drains are given by (those at n-type drains are similar):

$$\begin{matrix}P ( {SE}^{( i )} \vert {HC}_{p}^{( f )} ) = \int {\int }_{( q , {t}_{ce} ) ∈ {S}_{c , p}^{( j )}} {f}_{Q } ( q ) {f}_{T} ( {t}_{ce} ) ⅆ {t}_{ce} ⅆ q & Equation ( 8 ) \\ P ( {SE}^{( i )} \vert {HS}_{p}^{( i )} ) = \int {\int }_{( q , {t}_{ce} ) ∈ {S}_{c , p}^{( i )}} {f}_{Q } ( q ) {f}_{T} ( {t}_{ce} ) ⅆ {t}_{ce} ⅆ q & Equation ( 9 ) \\ P ( {SE}^{( i )} \vert {HM}_{p}^{( i )} ) = {\int }_{{Q}_{crit , m , p}^{( i )}}^{∞} {f}_{Q} ( q ) ⅆ q & Equation ( 10 )\end{matrix}$$

where S_{c,p}^{(j)} and S_{s,p}⁽ⁱ⁾ are sets of soft-error-inducing (q, t_{ce}) combinations corresponding to effective particle hits at the p-type drain of a j^{th} internal circuit node and an i^{th} DFF sample stage, respectively. The parameter Q_{crit,m,p}⁽ⁱ⁾ is the critical charge for the i^{th} DFF hold stage, if the effective particle hit occurs at the p-type drain. The functions ƒ_{Q}(q) and f_{T}(t_{ce}) are the probability density functions (PDF) of collected charge and sampling clock edge arrival time, respectively. Because a particle hit is independent of the clock edge arrival, ƒ_{T}(t_{ce}) may be a uniform distribution in the range [0, T_{clk}], where T_{clk} is the clock period. The function ƒ_{Q}(q) includes an exponential distribution.

The hold stage of a DFF is similar to a 6-T SRAM cell and can be characterized with a single critical charge value Q_{crit}. Its soft error rate is derived from Equations (2), (3), (5), (10) and the equations from above are:

$$\begin{matrix}{SER}_{ hold}^{( i )} = ( {A}_{ m , p}^{( i )} \cdot {\int }_{ {Q}_{ crit , m , p}^{( i )}}^{∞} {f}_{ Q} ( q ) ⅆ q + \\ {A}_{ m , n}^{( i )} \cdot {\int }_{ {Q}_{ crit , m , n}^{( i )}}^{∞} {f}_{ Q} ( q ) ⅆ q ) \cdot \\ {\int }_{{E}_{n , min}}^{{E}_{n , max}} {F}_{n} ( {E}_{n} ) ⅆ {E}_{n} \cdot α\end{matrix} \qquad Equation ( 11 )$$

where the first term in the parentheses corresponds to a 0→1 error if a particle hit occurs at the p-type drain. The second term is for a 1→0 error if a particle hit occurs at the n-type drain. Conventional SER evaluation of a DFF or an SRAM conventionally assumes Q_{crit,m,p}⁽ⁱ⁾=Q_{crit,m,n}⁽ⁱ⁾=Q_{crit,m}⁽ⁱ⁾, which is justified by proper design of a static CMOS gate so that the pull-up and pull-down paths have equal strengths. Under this condition, equation (11) is simplified to

$${SER}_{hold}^{( i )} = ( {A}_{m , p}^{( i )} + {A}_{m , n}^{( i )} ) \cdot {\int }_{{Q}_{crit , m}^{( i )}}^{∞} {f}_{Q} ( q ) ⅆ q \cdot F \cdot α \qquad Equation ( 12 )$$

where F is the total neutron flux within the whole energy spectrum.

The SER of a single SRAM cell is given by the empirical model as follows:

$${SER}_{SRAM} = F \cdot ( {A}_{d , p} + {A}_{d , n} ) \cdot K \cdot {ⅇ}^{- \frac{{Q}_{crit}}{{Q}_{s}}} \qquad Equation ( 13 )$$

where A_{d,p} and A_{d,n} are the p-type and n-type drain diffusion areas, K is a technology-independent fitting parameter, and Qₛ is the collection slope which varies with technology.

Evaluation of Equations (12) and (13) provides.

$$\begin{matrix}α = K & Equation ( 14 ) \\ {A}_{m , p}^{( i )} = {A}_{d , p} & Equation ( 15 ) \\ {A}_{m , n}^{( i )} = {A}_{d , n} & Equation ( 16 ) \\ {f}_{Q} ( q ) = \frac{1}{{Q}_{s}} {ⅇ}^{- \frac{q}{{Q}_{s}}} & Equation ( 17 )\end{matrix}$$

As both K and Qₛ have been previously characterized, and A_{d,p}. and A_{d,n} are available from circuit layout, Equations (14)-(17) will be used. The sensitive areas of an internal circuit node and DFF sample stage node are assumed to be the corresponding drain areas. The sensitive area may be related to the charge collection mechanism and should not differ if the circuit node belongs to a DFF or logic gate.

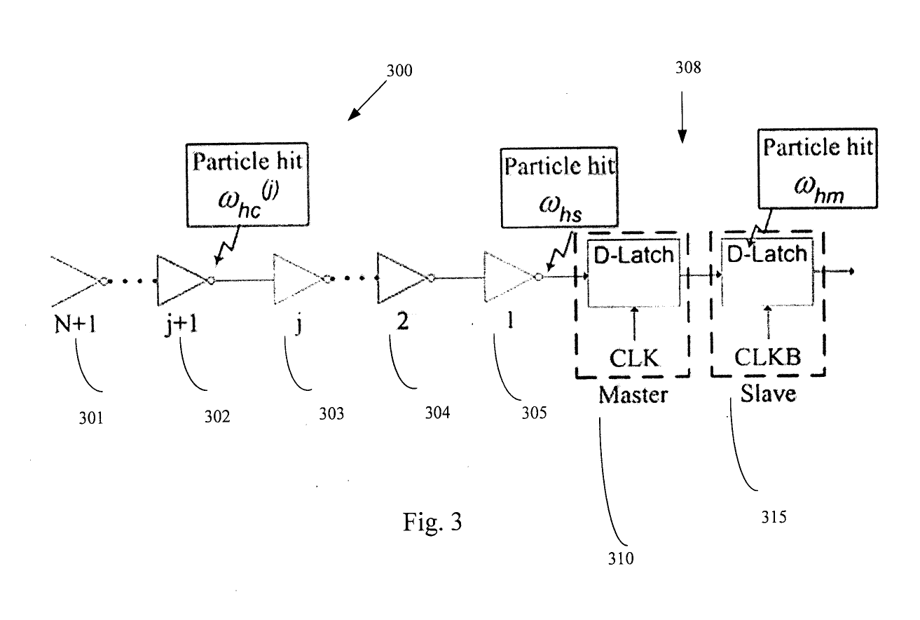

FIG. 3 illustrates a block diagram of a circuit simulation for conditional probabilities extracted from an inverter chain 300. As shown, an inverter chain circuit with (N+1) inverters (301-305) is used with a DFF 308 at the final output. Two conditions are implied: no fan-ins or fan-outs; and no logical masking.

The current waveform in Equation (7) is applied at one of the (N+2) locations (N internal circuit nodes, one DFF sample 310 and one DFF hold stage 315). The effect of the current waveform is determined by the value of q and t_{ce} as illustrated previously in FIG. 2. Equally-spaced data points are chosen in the set A defined as follows:
A=|0,Qₘₐₓ|×[0, T_{clk}| Equation (18)

with step sizes of Δq and Δt, respectively.

For every particle hit location, a flag function F(q, t_{ce}), defined to equal one when there is a soft error and zero when no error occurs, is obtained from simulation, such as HSPICE simulations. The discretization of Equations (8)-(10) as applied to the inverter chain circuit results in:

$$\begin{matrix}P ( SE \vert {HC}_{p}^{( j )} ) = {\sum }_{( q , {t}_{ce} ) ∈ A} {f}_{Q} ( q ) Δ {qf}_{T} ( {t}_{ce} ) Δ {t}_{ce} {F}_{{HC}_{p}^{( j )}} ( q , {t}_{ce} ) & Equation ( 19 ) \\ P ( SE \vert {HS}_{p} ) = {\sum }_{( q , {t}_{ce} ) ∈ A} {f}_{Q} ( q ) Δ {qf}_{T} ( {t}_{ce} ) Δ {t}_{ce} {F}_{{HS}_{p}} ( q , {t}_{ce} ) & Equation ( 20 ) \\ P ( SE \vert {HM}_{p} ) = \{ \begin{matrix}{\sum }_{q = {Q}_{crit}}^{{Q}_{max}} {f}_{Q} ( q ) Δ q & , {Q}_{crit} < {Q}_{max} \\ 0 & , {Q}_{crit} \geq {Q}_{max}\end{matrix} & Equation ( 21 )\end{matrix}$$

where a finite value Qₘₐₓ is used as the upper limit in the summation in Equation (21). This may reduce the simulation run times. The error caused by this approximation is less than 2% if Qₘₐₓ₌4Qₛ, due to the exponential distribution in Equation (17).

While analyzing or simulating circuits that include sequential elements such as the ones shown in FIG. 3, initial states of the sequential elements must be considered. There are two possible scenarios when a DFF latches an input value from the preceding logic. First, an initial state of the DFF and the next state after the clock edge may be identical. In this scenario, a SET can manifest itself by having itself latched by the DFF and hence upsetting the correct initial state of the DFF. This qualitatively suggests that the smaller the setup and hold times are, the more likely the SET pulse can be latched into the DFF.

Second, the initial state of the DFF and the next state after the clock edge may be different. In this scenario, the presence of a SET will reduce the time available for the correct input to get latched, which qualitatively suggests that larger setup and hold times result in higher SERs.

Of the two scenarios, the first scenario is more likely to occur than the second because a large fraction of the path delay in a high-performance microprocessor is significantly less than the clock cycle time, which means the correct data value has already propagated into the master stage of the DFF before the clock edge; and data activity factor at a DFF input in a high performance microprocessor is usually very small (e.g, less than 10%), which means the data to be latched into the DFF during the current clock cycle is most likely the same as the data stored in the DFF from the last clock cycle. In a preferred embodiment, the initial state of the DFF and the next state are assumed the same.

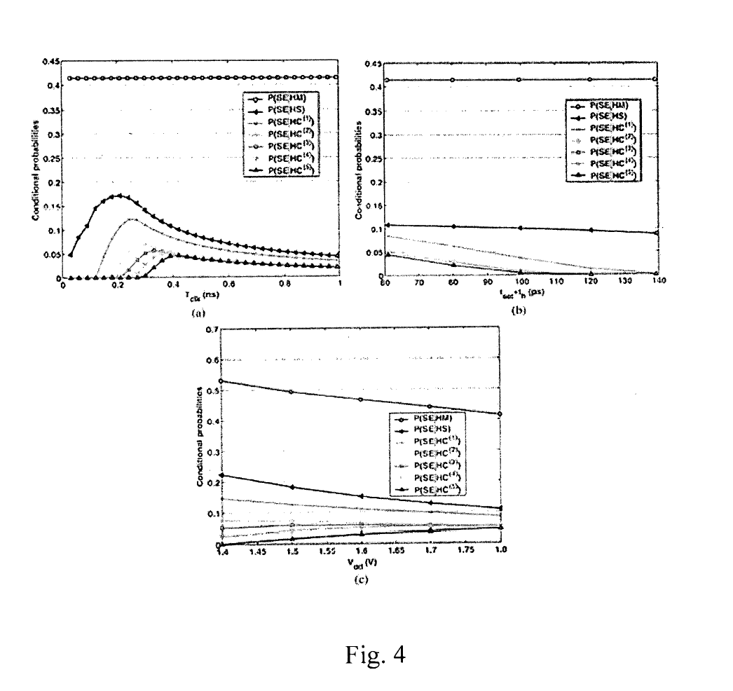

FIGS. 4a-4c illustrate graphs of conditional probabilities of soft error. In a preferred embodiment, the soft error conditional probabilities in Equations (19)-(21) and those corresponding to particle hits at n-type drains (similarly derived) are evaluated with a Taiwan Semiconductor Manufacturing Company (TSMC) 0.18 μm technology. The average of conditional probabilities corresponding to p and n-type drains are illustrated in FIGS. 4a-4c.

FIG. 4(a) illustrates the conditional probabilities as non-monotonic functions of clock period T_{clk}. The conditional probabilities are zero when T_{clk} is small because the uniformly distributed sampling clock edge always arrives before the SET arrival at the DFF input. The conditional probabilities start to increase when T_{clk} is large enough such that the propagated SET starts to encompass the DFF latching window (see FIG. 2(b)). The curves in FIG. 4(a) peak when T_{clk} is approximately equal to the pulse delay t_{d}. The conditional probabilities drop when T_{clk} becomes so large that the fraction of clock edges arriving later than the SET arrival keeps increasing with T_{clk}. In the TSMC 0.18 μm process, the conditional probability P(SE|HM) is at least two times greater than the other conditional probabilities. The other conditional probabilities, though small, have significant impact on the overall SER because a logic circuit usually has many more combinational circuit nodes than memory nodes (DFF hold stages). In addition, P(SE|HC^{(j)})>P(SE|HC⁽ⁱ⁾) if j<i. This is due to the attenuation of the SET in both amplitude and duration when the SET propagates through the inverter chain.

FIG. 4(b) shows that an increasing DFF latching window duration (tₛₑₜ+tₕ) results in a reduction of conditional soft error probabilities. This is because a master-slave DFF with a wider latching window is less sensitive to fast-switching SETs. Other DFF styles, such as those with a semi-dynamic front-end, can be used in this simulation setup as well to obtain the corresponding conditional probabilities.

FIG. 4(c) shows that different conditional probabilities vary differently with supply voltage V_{dd}. The conditional probabilities P(SE|HS), P(SE|HC⁽¹⁾) and P(SE|HC⁽²⁾) decrease with V_{dd} because the SET generation mechanism, which dominates for nodes closer to the DFF, and becomes weaker at higher V_{dd} due to stronger active pull-up or pull-down path in the gates. The conditional probabilities P(SE|HC⁽⁴⁾) and P(SE|HC⁽⁵⁾) increase with V_{dd} because the delay between SET generation and SET arrival at DFF input plays a dominant role for nodes farther away from the DFF. The delay decreases as V_{dd} increases and hence it is more likely for the pulse to get latched. The conditional P(SE|HC⁽³⁾) happens to occur in the transition region between two regimes and is non-monotonic with V_{dd}.

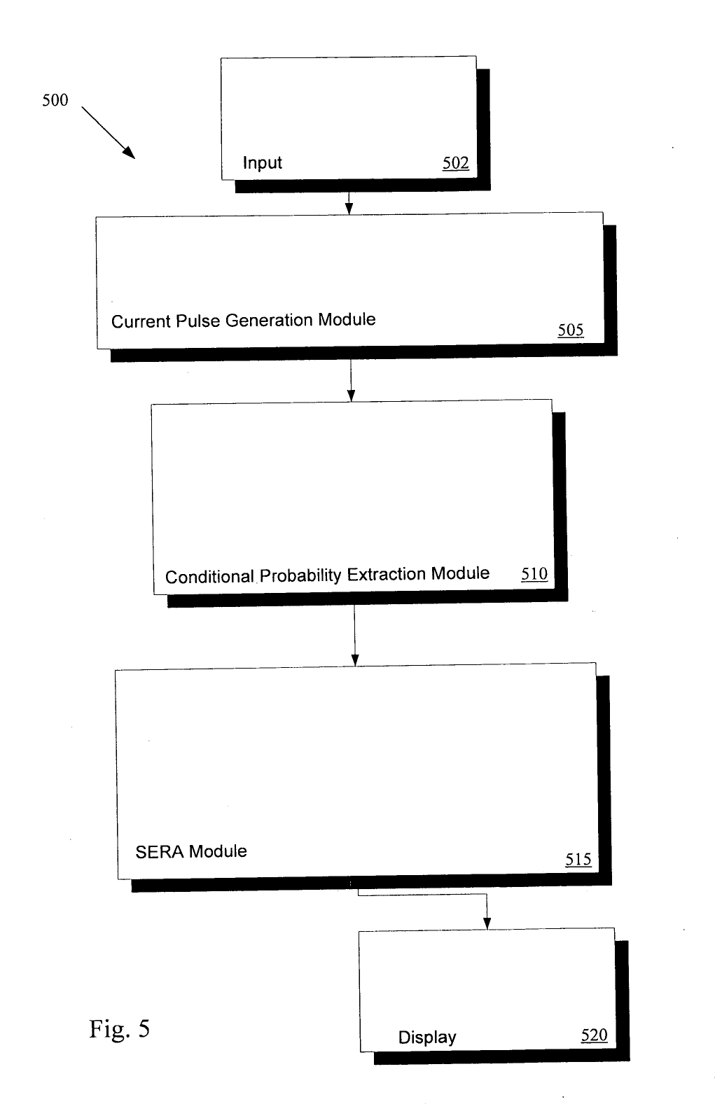

FIG. 5 illustrates a system 500 that correlates a set of parameters of the electronic system with a calculated soft error rate. The system 500 includes a Current Pulse Generation Module 505, a Conditional Probability Extraction Module 510, and a Soft Error Rate Analysis (SERA) Module 515. The system 500 may also include an input module 502 and an output module, such as a display 520. In a preferred embodiment, the Current Pulse Generation Module 505 provides a circuit simulation compatible transient noise source to emulate the effect of a particle strike. The current pulse model may be used as shown in Equation (7). More specifically, a circuit is decomposed into a collection of circuit nodes with a gate between each pair of nodes. The gate is modeled as an equivalent inverter. This gate modeling results in multiple inverter chains. The Current Pulse Generation Module 505 may provide a current waveform from a device simulation to the Conditional Probability Extraction Module 510.

To improve accuracy, circuit factors may be accounted for, such as transistor sizing and multiple fan-ins reflected by changing the size of equivalent inverter; extra load due to fan-outs modeled by adding a capacitor to the output of each inverter; and logical masking is emulated.

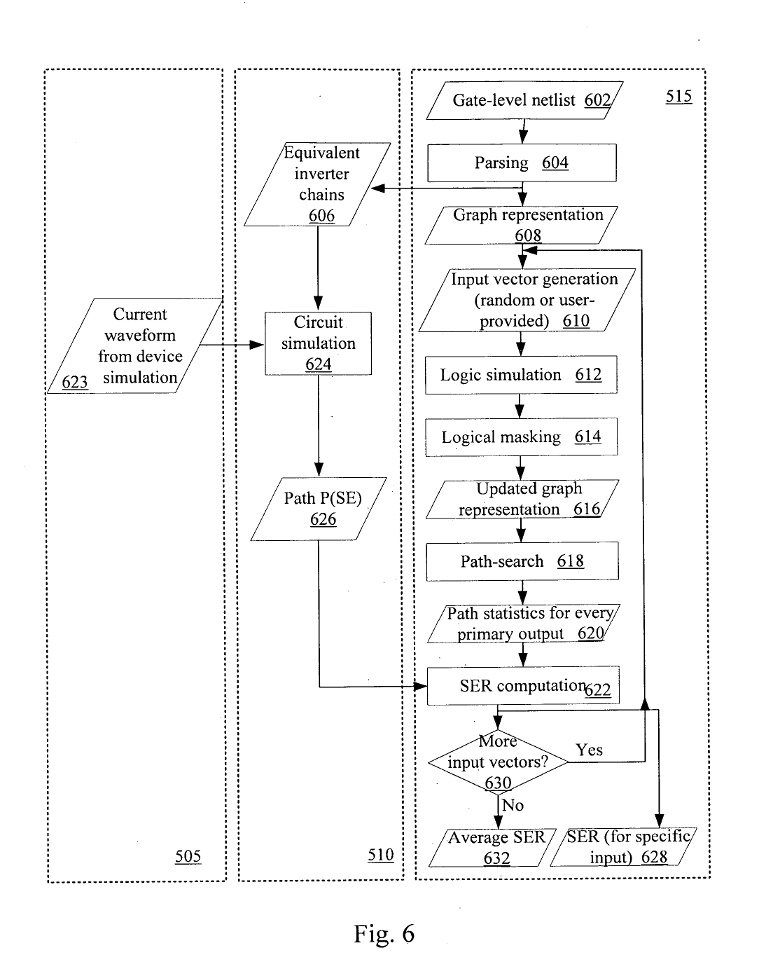

The Conditional Probability Extraction Module 510 determines conditional probabilities for the electronic system, based on Equation 5 as discussed above. The Conditional Probability Extraction Module 510 executes circuit simulations based on inputs from the Current Pulse Generation Module 505 and related waveforms and processes equivalent inverter chains derived from graph representations of an electronic system. The Conditional Probability Extraction Module 510 may determine the conditional probabilities from data stored in a memory device or storage coupled with the system 500, such as from a look-up table. The Conditional Probability Extraction Module 510 also may be configured to determine path lengths along the graph of the equivalent representation, calculating a number of inverters along a path, related to soft error calculations. The SERA Module 515 computes the soft error rate of a combinational circuit based on results from the first two modules, as illustrated in FIG. 6.

FIG. 6 illustrates interrelated acts that may be taken to improve the reliability of an electronic system using the SERA process. At block 602, a gate-level representation of the electronic system, such as a gate-level netlist is provided. The gate-level netlist may be determined at run-time, or may be loaded from a storage or memory device. At block 604, the SERA Module 515 performs a parsing, such as converting the gate-level representation to a graph. In an exemplary embodiment, vertices and edges of the graph correspond to internal circuit nodes and gates of the circuit-level representation of the electronic system, respectively. A path length denotes the number of gates between two circuit nodes. The parsing may only need to be done once for a given circuit. The gate-level netlist also contains transistor sizing information so that an equivalent inverter chain can be extracted to obtain soft error probabilities on a path, at block 606, at the Conditional Probability Extraction Module 510.

The Conditional Probability Extraction Module 510 may perform a circuit simulation of the electronic system, at block 624. The circuit simulation may be used to generate the conditional probabilities associated with the graph representation of the electronic system, based on Equation (5), for example. In another exemplary embodiment, the Conditional Probability Extraction Module 510 also provides a path P(SE) based on a soft error rate, at block 626. The path P(SE) is provided to the SERA Module 515 to determine an SER computation.

At block 608, a graph representation of the converted gate-level netlist is provided. At block 610, user-provided or randomly-generated input vectors are processed. At blocks 612 and 614, a logical masking mechanism is accounted for. To account for the logical masking mechanism, the logic values of all vertices are first computed based on the input vectors. For every vertex, its logic value is temporarily adjusted, such as by flipping its logic value, to determine whether the value can propagate through an edge to an adjacent vertex. The adjacency list representation of the circuit is then updated to emulate the logical masking mechanism, at step 616.

More specifically, the element in the adjacency list that corresponds to a path between the i^{th} and j^{th} nodes will be removed if flipping the logic value at the i^{th} node does not change the value at the j^{th} node. In step 618, a path-search process based on a conventional depth-first search (DFS) process is used to find all paths between a given pair of primary output bit and internal circuit node. Other path-search processes may be used. The length of each path is also recorded. If multiple paths exist between a pair of nodes (such as a reconvergent fan-out), circuit simulation shows that the noise pulse generated by a particle hit can propagate along various paths and arrive at DFF input at different instants with small or no overlap due to different path delays. Path statistics for every primary output are determined, at block 620.

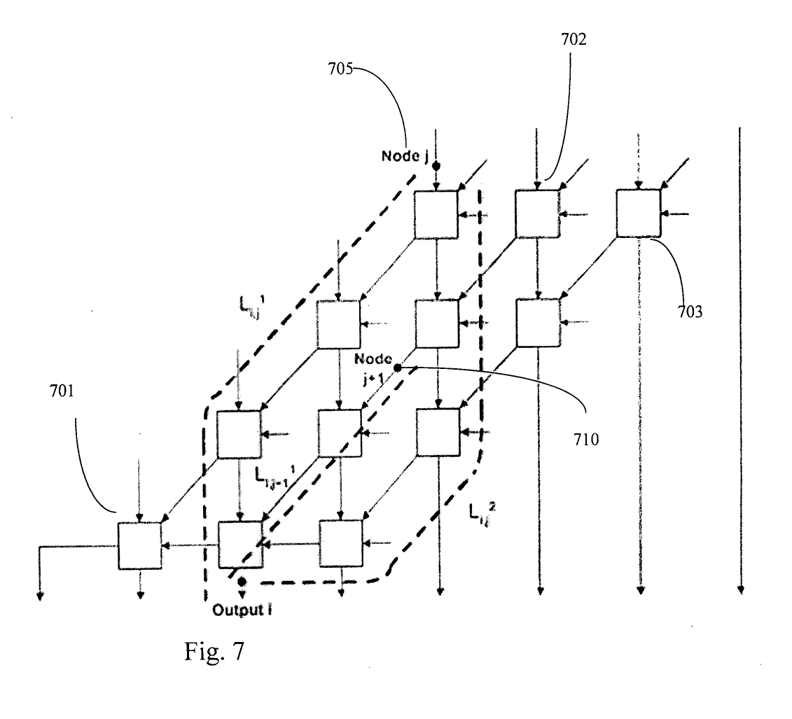

Next, the SER computation for the electronic system is performed, at block 622. FIG. 7 is a block diagram illustrating a SER contribution from internal circuit nodes (such as 701, 702 and 703). The following approximation holds for the soft error probability at ith primary output bit conditioned on an effective particle hit at jth internal circuit node as illustrated in FIG. 7:

$$\begin{matrix}P ( {SE}^{( i )} \vert {HC}_{p}^{( j )} ) ≃ \{ \begin{matrix}min ( 1 , {\sum }_{k = 1}^{{N}_{i , j}} {p}^{( {L}_{i , j , p}^{k} )} ) & , V ( j ) = 0 \\ 0 & , V ( j ) = 1\end{matrix} & Equation ( 22 ) \\ P ( {SE}^{( i )} \vert {HC}_{n}^{( j )} ) ≃ \{ \begin{matrix}0 & , V ( j ) = 0 \\ min ( 1 , {\sum }_{k = 1}^{{N}_{i , j}} {p}^{( {L}_{i , j , n}^{k} )} ) & , V ( j ) = 1\end{matrix} & Equation ( 23 )\end{matrix}$$

where V(j) is the logic value of node j, Nᵢⱼ is the number of unique path lengths between the j^{th} internal circuit node and the i^{th} primary output bit, L_{i,j,p}^{k} is the k^{th} path length corresponding to a particle hit at p-type drain, L_{i,j,p}^{k} is the k^{th} path length corresponding to a particle hit at n-type drain, and P_{i,j,p}^{(L}^{^{k}}⁾ or P_{i,j,n}^{L}^{^{k}}⁾ is the corresponding conditional soft error probability for the inverter chain circuit shown previously in FIG. 3. Paths with unique lengths are accounted for. This approximation results in a slight over-estimation of the conditional probabilities because the propagation of a noise pulse along two paths with the same length may weaken, if not cancel, each other. This approximation does not result in significant degradation in estimation accuracy for most circuits.

The soft error probability, and hence SER of the i^{th} bit is

$$\begin{matrix}{SER}^{( i )} = Fα [ {\sum }_{j = 1}^{M} ( P ( {SE}^{( i )} \vert {HC}_{p}^{( j )} ) {A}_{c , p}^{( j )} + P ( {SE}^{( i )} \vert {HC}_{n}^{( j )} ) \\ {A}_{c , n}^{( j )} ) + P ( {SE}^{( i )} \vert {HS}_{p}^{( j )} ) {A}_{n , p}^{( i )} + P ( {SE}^{( i )} \vert {HS}_{n}^{( j )} ) \\ {A}_{i , n}^{( j )} + P ( {SE}^{( i )} \vert {HM}_{p}^{( j )} ) {A}_{m , p}^{( i )} + P ( {SE}^{( i )} \vert {HM}_{n}^{( i )} ) {A}_{m , n}^{( j )} ]\end{matrix} \qquad Equation ( 24 )$$

where the conditionals P(SE⁽ⁱ⁾|HCₚ^{(j)}) and P(SE⁽ⁱ⁾|HCₙ^{(j)}) are calculated from Equations (22)-(23) while the other conditionals are calculated from Equations (20)-(21).

The SERA Module 515 may output the SER for a specific input, at block 628. The SERA Module 515 may display the output on a display 520, or may store the SER in a storage or memory device coupled with the system 500. The SERA Module 515 may determine if more input vectors are to be processed, at block 630. If more input vectors are to be processed, the SERA Module 515 continues with block 610 with the additional input vectors. If no more input vectors are to be processed, the SERA Module 515 may perform an averaging of variations in SER for different input vectors, at block 632.

The method illustrated in FIG. 6 may be used to design an electronic system with an improved reliability. The electronic system may comprise a sequential logic circuit or a combinational logic circuit, with a plurality of logic gates and/or a plurality of storage elements. A set of parameters may be correlated to the evaluated soft error rate, such as that determined in block 628. The set of parameters may comprise parameters related to the design of an electronic system, such as a number of logic gates or a number of storage elements, a location of the logic gate, a location of the storage element, a logic gate speed, a logic gate fan-out, a clock speed, a supply voltage, or a length of interconnects between logic gates or storage elements. The set of parameters may also include a transistor size, a logic depth, a circuit topology, a clock speed, a gate speed, a supply voltage scaling, logic topology, or a gate circuit design.

In an example embodiment, an electronic system is designed by selecting logic gates and storage elements based on the set of parameters and arranging the logic gates and storage elements. The logic gates and the storage elements may be arranged to maximize the reliability of the electronic system based on the evaluated soft error rate and the set of parameters. The electronic system may be designed with a conventional computer-aided design (CAD) system.

As described before, the SERA system employs a mix of probability theory, circuit simulation, graph theory and fault simulation. Referring back to FIG. 6, SERA takes a hierarchical divide-and-conquer approach in modeling the SER of a combinational circuit. The effect of a particle strike is modeled by a current pulse as described. The current pulse model is derived from 3-D device simulations and can be calibrated with experiments. It can be integrated into circuit simulations.

Second, circuit simulations are employed in the Conditional Probability Extraction Module 510 to provide conditional soft error probabilities. The current pulse model is used in the simulations to maintain the best possible accuracy. Simulation times will not be prohibitive because such simulations are run on a selected set of inverter chains. Electrical and timing masking mechanisms are accounted for in this step, as described herein.

Third, fault simulations and graph theory are employed in the Soft Error Rate Analysis Module 515. This takes logic masking into account while keeping the simulation time manageable because these algorithms are orders of magnitude faster than device or circuit level simulations.

Finally, the probability theory outlined above is the foundation of SERA and brings the above three pieces of information together and yield the end product of the analysis, the soft error rate at any output bit of a given circuit as illustrated by Equation (24).

The SERA methodology has been described in the context of cosmic ray soft errors. However, the SERA methodology can be extended to analyze any transient noise problem. For example, alpha particle induced soft error can be analyzed by replacing the current pulse model in (7) with the following Equation:

$$I ( t ) = {I}_{0} ( {ⅇ}^{- \frac{t}{{τ}_{1}}} - {ⅇ}^{- \frac{t}{{τ}_{2}}} ) \qquad Equation ( 25 )$$

where I₀ is the approximate maximum current, τ₁ is the collection time constant for junction, and τ₂ is the ion track establishment time constant. The probability density function of injected charge and particle hit rate can also be updated. The Soft Error Rate Analysis Module 515 will not need to be changed, except now that it may utilize a new conditional soft error probability based on the above changes.

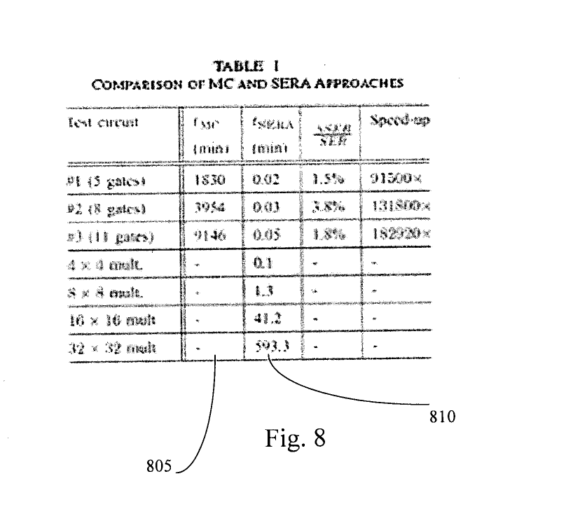

FIG. 8 illustrates a comparison between the results of a SER analysis 810 with those of empirical model and Monte Carlo simulation 805 is provided. A SER analysis is shown to achieve excellent accuracy with orders of magnitude reduction in run times. The effect of logical masking and input vector value on SER of combinational logic circuits are also shown. The estimated SER for multipliers of various size as an example is provided. The dependence of SER on supply voltage and DFF latching window is explicitly shown.

Generally, empirical SER data for combinational circuits may not be available. Therefore, the proposed SERA methodology is validated by a two-step approach. The results from SERA are first compared with existing empirical SER data for SRAMs, knowing that an SRAM cell is nothing but a special case of CCLC. Study of SER as a function of supply voltage for 6-T SRAM cells in 0.35 μm and 0.6 μm, processes shows consistent results. The worst case difference is 8% and may be attributed to the difference in process parameters.

Secondly, Monte Carlo circuit simulations may be used to verify the SER of a few small test circuits predicted by SERA. The number of simulated random events required in a Monte Carlo simulation for statistically significant predictions of SER depends inversely on the actual error rate. For example, if the failure rate expected from simulation is 10⁻¹⁶ errors/sec, which is a typical SER value for a single SRAM cell, of the order of 10⁻¹⁸ simulated events would be appropriate to achieve statistical significance. The sample sizes typically needed in SER Monte Carlo simulation may preclude the direct use of a nuclear interaction or semiconductor device simulation program.

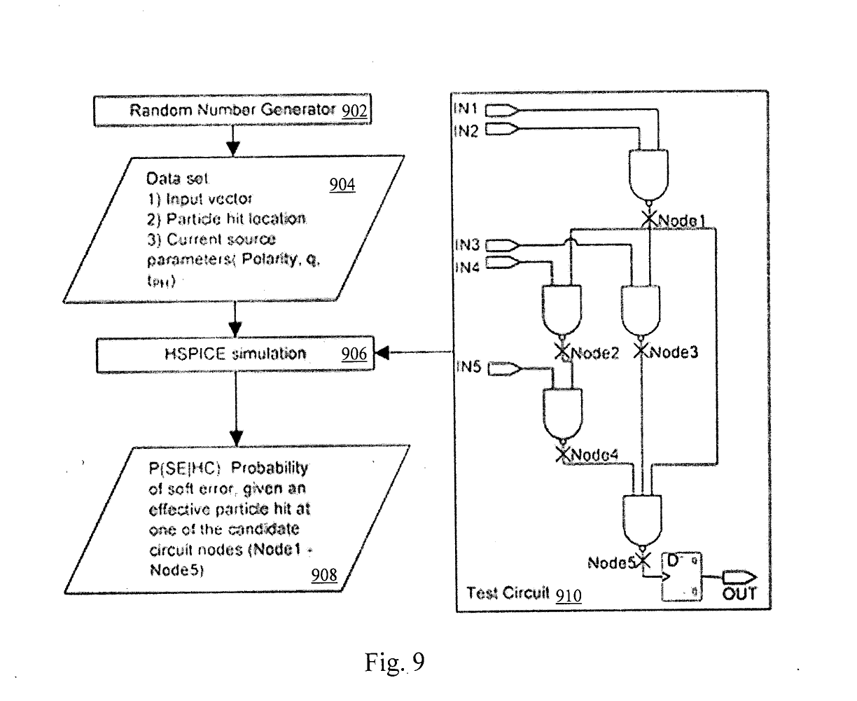

FIG. 9 illustrates a Monte Carlo simulation flowchart which may be used for SERA validation. A random number generator provides data, at block 902, for a data set. Monte Carlo simulations may be performed using HSPICE. A data set is generated pseudo-randomly, at block 904, each entry of which is composed of input vectors, particle hit location and pulse current source parameters. This data set is then provided to HSPICE to perform data-driven transient simulations, at block 906. A test circuit, such as a combinational circuit 910, may be used to provide data to the HSPICE simulation at block 906. The HSPICE simulation results are then used to determine conditional probabilities, at block 908. For example, the Monte Carlo simulation may determine the probability of a soft error, given an effective particle hit at one of candidate circuit nodes from the combination circuit 910.

Comparisons were conducted on a Dell Precision Workstation 650n (with Intel Xeon 2.8 GHz CPU and I GB RAM) running Redhat Linux. In FIG. 8, the run times of SERA (t_{SERA}) and one million Monte Carlo simulations (t_{MC}), as well as the difference between their SER results

$$( \frac{Δ SER}{SER} )$$

and run time speed-up are shown. Excellent matching (less than 4% difference) were observed with 90000x-180000x speed-up for three small circuits with 5, 8, and 11 gates, respectively. The total run time of Monte Carlo circuit simulation grows so rapidly with the number of gates that it is impractical to simulate a 4×4 multiplier. SERA, on the other hand, can analyze large circuits.

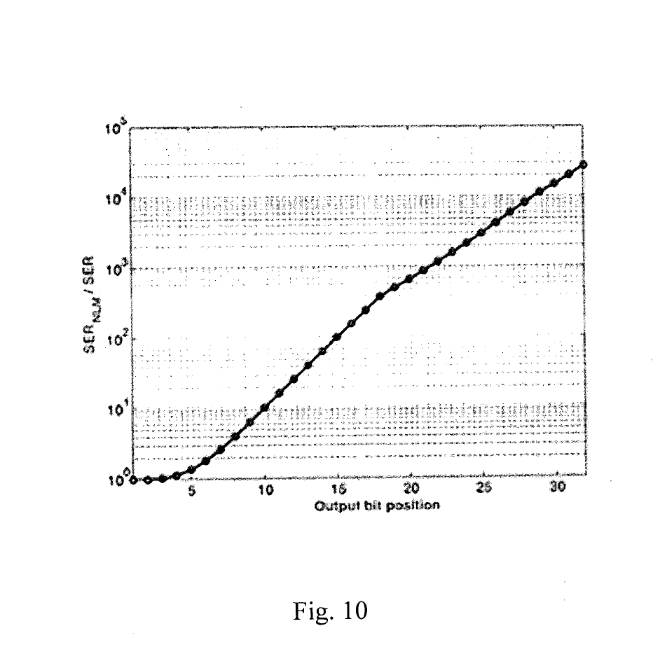

FIG. 10 illustrates a graph of a normalized SER. This graph shows the importance of taking logical masking into account. Ignoring logical masking may result in an unreasonable over-estimation of SER, especially for the most significant bits (MSBs).

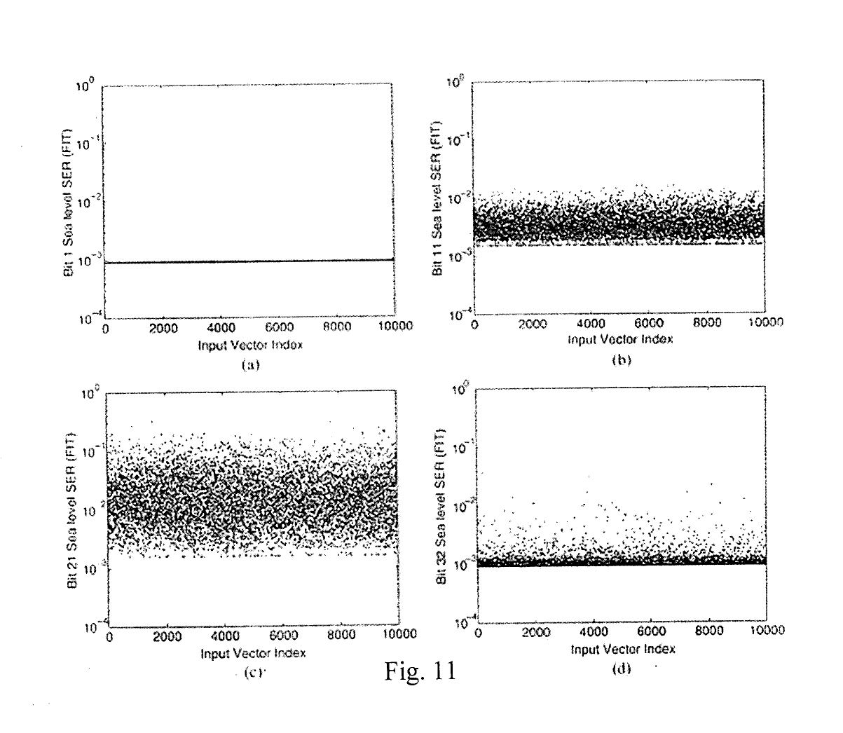

FIGS. 11a-d illustrate graphs of SER as functions of input vectors. These graphs show the variation of SER with input vector values. SER values for the center bits tend to spread more than the least significant bits (LSBs) and MSBs, because logical masking mechanism varies more with input vector values due to the large number of paths leading to those bits.

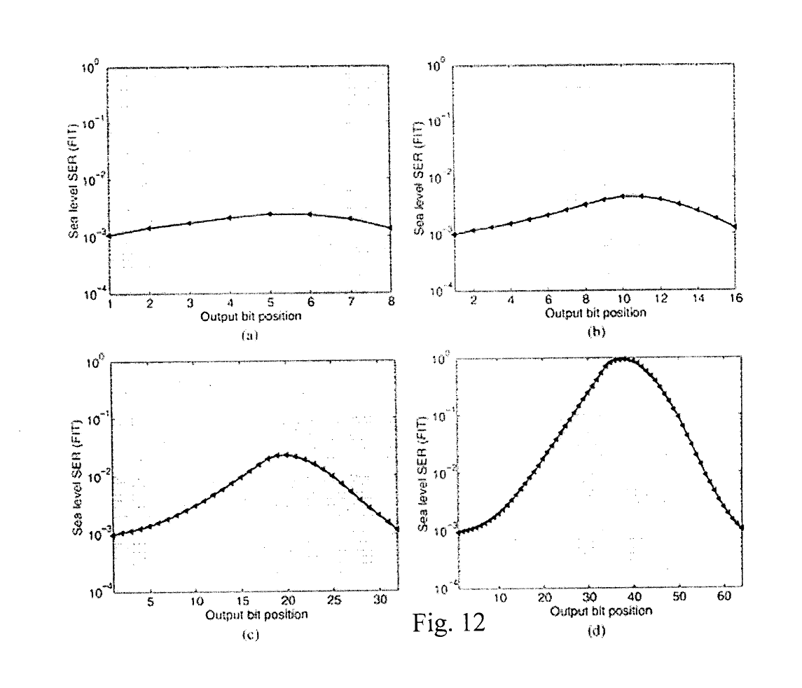

FIGS. 12a-d illustrate graphs of SER as functions of individual bits of multipliers of various sizes. The SER averaged over 10000 input vector values are shown for individual bits of parallel carry-save array multipliers of various sizes under nominal supply voltage and clock frequency. Two factors influence the SER for an output bit: the number of paths between the output bit and any internal circuit node, and logical masking. The former dominates for LSBs while the latter dominates for MSBs. This results in the peaking of individual bit SER at a bit position roughly two thirds of the full output precision away from the LSB. In FIGS. 12a-d, the fraction of SER contributed by DFF memory element for multipliers of various sizes. As the size of multiplier increases, less and less SER is contributed by the DFF memory element. Both upper and lower bounds on the overall SER are calculated from (2) and (6) as follows:

$${max}_{i} {SER}^{( i )} \leq SER \leq {\sum }_{i = 1}^{B} {SER}^{( i )} \qquad Equation ( 26 )$$

where B is the number of output bits.

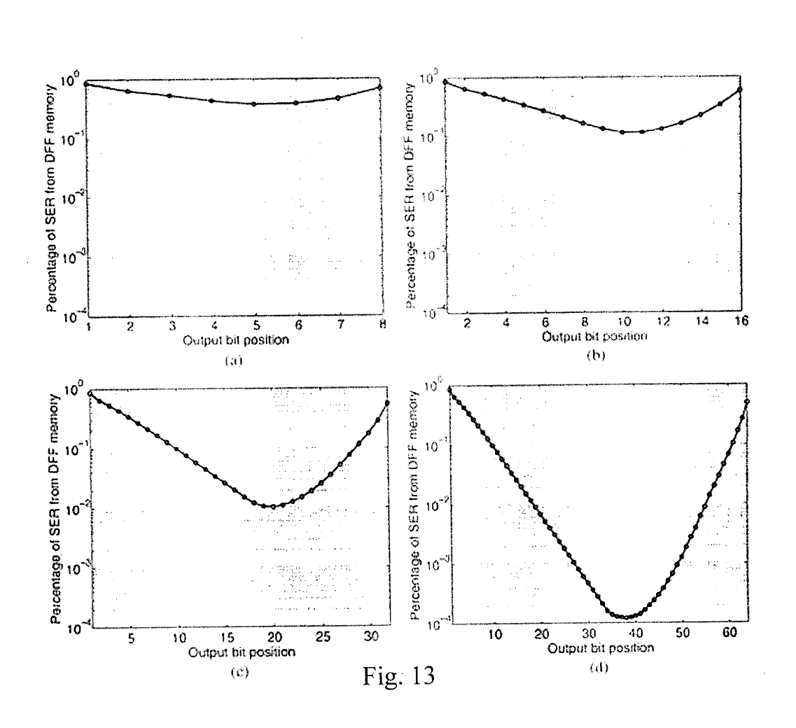

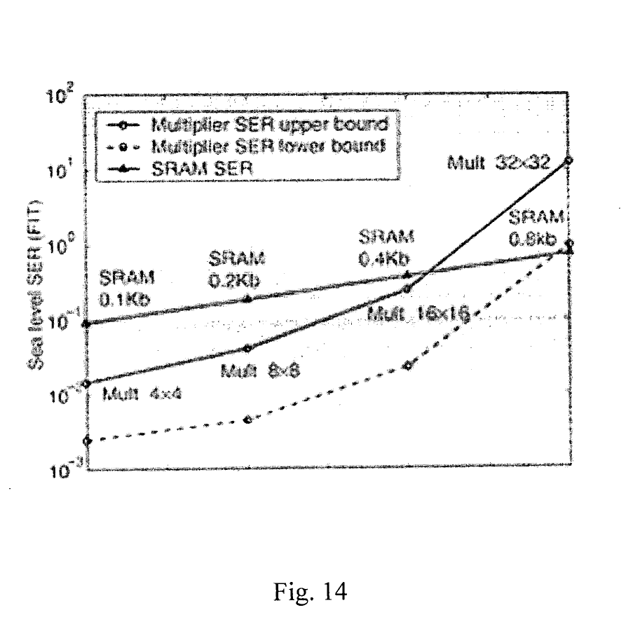

FIGS. 13a-d show graphs of the contribution of soft error rate from different memory elements. FIG. 14 illustrates a comparison of SER for SRAMs of various sizes. The SER lower bound of a 32×32 multiplier is close to the SER of a 1 kb SRAM in the same technology while its upper bound is close to SER of a 10 kb SRAM.

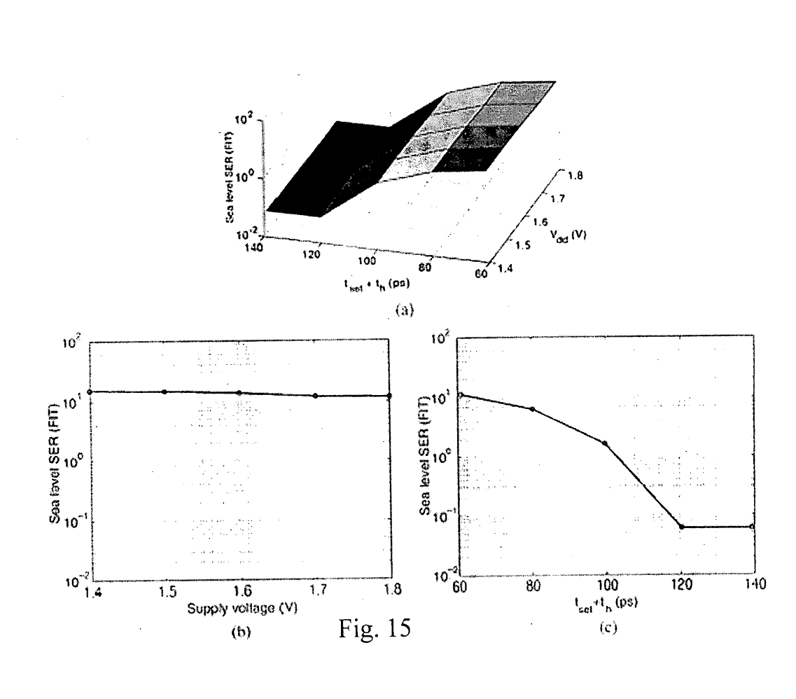

The SER of a 32×32 multiplier is further plotted as a function of supply voltage V_{dd} and DFF latching window t_{sct}+tₕ in FIG. 15. A wider latching window can very effectively decrease the error latching probability (see FIG. 4(b)) and hence the soft error rate. The P(SE|HM) terms do not depend on latching window and start to dominate after tₛₑₜ+tₕ is greater than roughly 120 ps so the reduction in SER thereafter becomes negligible. On the other hand, higher V_{dd} does result in a slight reduction of SER. This weak dependence of SER on V_{dd} is because the conditional probabilities are relatively weak functions of V_{dd} (see FIG. 4(c)). In fact, the SER increases by more than 50× when tₛₑₜ+tₕ is decreased by 20% from 120 ps while it increases by only 28% when V_{dd} is decreased by 20% from 1.8 V.

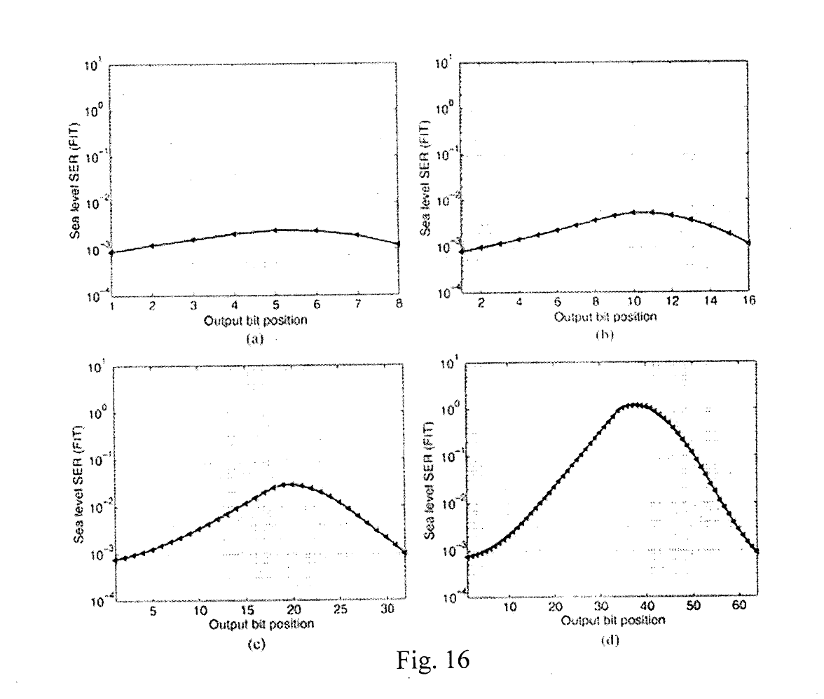

The impact of technology scaling on the SER of SRAM/latch circuits is known. FIG. 16 illustrates the SERs of multipliers of various sizes in an IBM 0.13 μm process technology analyzed with SERA. The SER peaking phenomenon can be observed for the multipliers as it is mainly determined by the logical masking mechanism, which does not vary with the process technology. On the other hand, the electrical and latching window masking mechanisms do vary with the circuit parameters, which are closely related to process technology.

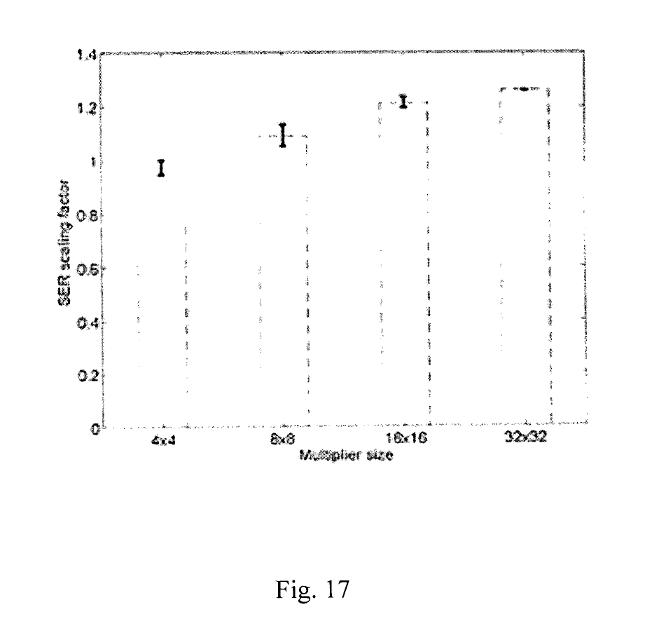

FIG. 17 illustrates the change in overall SER for different technology scaling. An increase of 0%-25% in SER for multiplier circuits of various sizes has been observed as technology scales from 0.18 μm to 0.13 μm. The SER of smaller circuits (such as a 4×4 multiplier) decreases slightly for the newer technology because the reduction in the drain area overwhelms the increase in the conditional soft error probabilities.

A soft error rate analysis (SERA) methodology for combinational and memory circuits has been disclosed. SERA is based on a modeling and analysis approach that employs a mix of probability theory, circuit simulation, graph theory and fault simulation. SERA may achieve five orders of magnitude speed-up over Monte Carlo based simulation approaches with less than 5% error. The proposed methodology reveals several results such as: the SER of combinational circuits is a much stronger function of the clock period and DFF latching window than supply voltage; multipliers show an SER peaking phenomenon where the SERs of MSBs and LSBs are three orders of magnitude lower than those of the center bits; the SER of certain combinational circuits can be comparable to or exceed that of SRAMs with similar area; and an increase of up to 25% in SER for multiplier circuits of various sizes has been observed as technology scales from 0.18 μm to 0.13 μm.

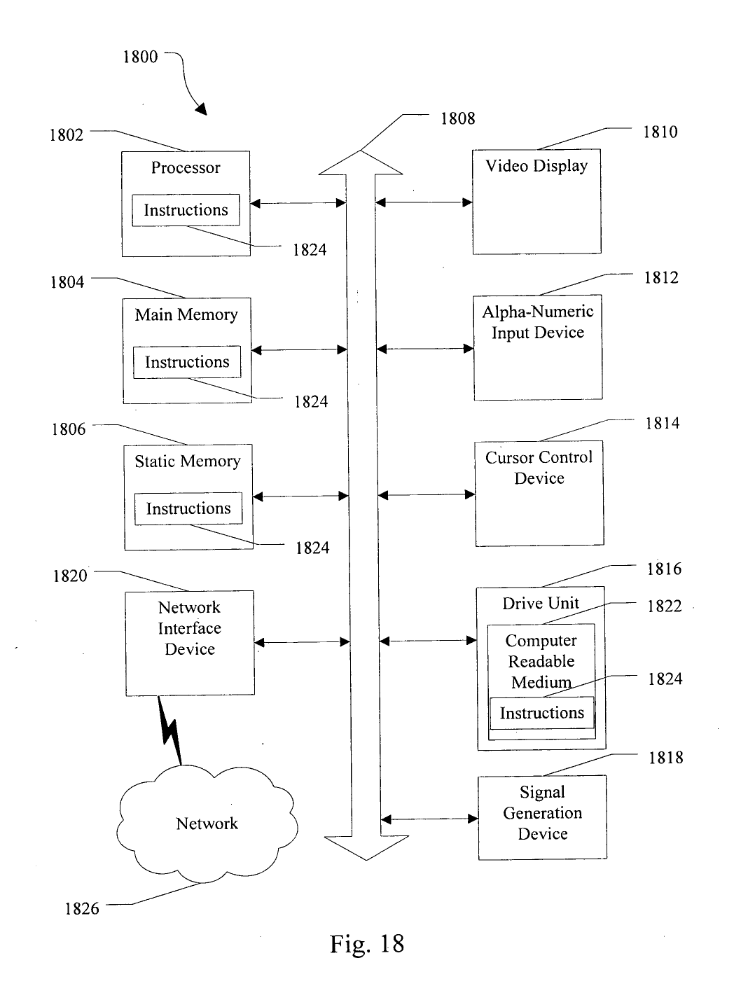

The proposed SERA method can be loaded and stored onto a program storage medium or device readable by a computer or other machine, embodying a program of instructions executable by the machine to perform the various aspects of the proposed method as discussed and claimed herein, and as illustrated in the figures. Referring to FIG. 18, an illustrative embodiment of a general computer system is shown and is designated 1800. The computer system 1800 can include a set of instructions that can be executed to cause the computer system 1800 to perform any one or more of the methods or computer based functions disclosed herein. The computer system 1800 may operate as a standalone device or may be connected, e.g., using a network, to other computer systems or peripheral devices.

In a networked deployment, the computer system may operate in the capacity of a server or as a client user computer in a server-client user network environment, or as a peer computer system in a peer-to-peer (or distributed) network environment. The computer system 1800 can also be implemented as or incorporated into various devices, such as a personal computer (PC), a tablet PC, a set-top box (STB), a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. In a particular embodiment, the computer system 1800 can be implemented using electronic devices that provide voice, video or data communication. Further, while a single computer system 1800 is illustrated, the term “system” shall also be taken to include any collection of systems or sub-systems that individually or jointly execute a set, or multiple sets, of instructions to perform one or more computer functions.

As illustrated in FIG. 18, the computer system 1800 may include a processor 1802, e.g., a central processing unit (CPU), a graphics processing unit (GPU), or both. Moreover, the computer system 1800 can include a main memory 1804 and a static memory 1806 that can communicate with each other via a bus 1808. As shown, the computer system 1800 may further include a video display unit 1810, such as a liquid crystal display (LCD), an organic light emitting diode (OLED), a flat panel display, a solid state display, or a cathode ray tube (CRT). Additionally, the computer system 1800 may include an input device 1812, such as a keyboard, and a cursor control device 1814, such as a mouse. The computer system 1800 can also include a disk drive unit 1816, a signal generation device 1818, such as a speaker or remote control, and a network interface device 1820.

In a particular embodiment, as depicted in FIG. 18, the disk drive unit 1816 may include a computer-readable medium 1822 in which one or more sets of instructions 1824, e.g. software, can be embedded. Further, the instructions 1824 may embody one or more of the methods or logic as described herein. In a particular embodiment, the instructions 1824 may reside completely, or at least partially, within the main memory 1804, the static memory 1806, and/or within the processor 1802 during execution by the computer system 1800. The main memory 1804 and the processor 1802 also may include computer-readable media.

In an alternative embodiment, dedicated hardware implementations, such as application specific integrated circuits, programmable logic arrays and other hardware devices, can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionality as described herein.

The present disclosure contemplates a computer-readable medium that includes instructions 1824 or receives and executes instructions 1824 responsive to a propagated signal, so that a device connected to a network 1826 can communicate voice, video or data over the network 1826. Further, the instructions 1824 may be transmitted or received over the network 1826 via the network interface device 1820.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random access memory or other volatile re-writable memory. Additionally, the computer-readable medium can include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although the present specification describes components and functions that may be implemented in particular embodiments with reference to particular standards and protocols, the invention is not limited to such standards and protocols. For example, standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same or similar functions as those disclosed herein are considered equivalents thereof.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

Various embodiments are described above to facilitate a thorough understanding of various aspects of the invention. However, these embodiments are to be understood as illustrative rather than limiting in nature, and those skilled in the art will recognize that various modifications or extensions of these embodiments will fall within the scope of the invention, which is defined by the appended claims.

1. A method for improving a reliability of an electronic system, the method comprising:
converting a gate-level representation of the electronic system to a graph, the graph having a vertex and an edge that correspond to nodes and gates of the electronic system;
generating input vectors, the input vectors corresponding to inputs supplied to the electronic system;
evaluating a soft error rate during a simulated operation of the electronic system; and
correlating the evaluated soft error rate to a set of parameters stored in a computer-readable medium,
where the set of parameters are used to configure the nodes and the gates of the electronic system with a maximized reliability based on the evaluated soft error rate.

2. The method of claim 1, where evaluating the soft error rate comprises correlating the soft error rate to at least one of an environmental factor, a circuit structure, or a usage model.

3. The method of claim 2, where the environmental factor comprises a particle flux or a probability density function of injected charge.

4. The method of claim 2, where the circuit structure comprises a transistor size, a logic depth, a circuit topology, a clock speed, a gate speed, a supply voltage scaling, logic topology, or a gate circuit design.

5. The method of claim 2, where the usage model comprises a plurality of input vectors.

6. The method of claim 1, where converting the gate-level representation comprises processing transistor sizing information so that an equivalent inverter chain is extracted to obtain soft error probabilities on a path of the graph.

7. The method of claim 1, further comprising processing the input vectors based on an averaging of the soft error rate associated with the input vectors.

8. The method of claim 1, further comprising determining a logical masking mechanism for the gate-level representation of the electronic system.

9. The method of claim 8, where determining the logical masking mechanism comprises:
determining a logic value of the vertex based on the input vectors;
for every vertex, temporarily adjusting the logic value to determine whether the logic value can propagate through an edge to an adjacent vertex; and
updating an adjacency list representation of the electronic system to emulate the logical masking mechanism.

10. The method of claim 9, where updating the adjacency list representation comprises removing an element in an adjacency list that corresponds to a path between a first node and a second node when flipping the logic value at the first node does not change a logic value at the second node.

11. The method of claim 1, further comprising:
performing a path-search process to find all paths between a determined pair of primary output bits and an internal circuit node; and
storing a length of each path.

12. The method of claim 11, where performing the path-search process comprises performing a depth-first search (DFS) process.

13. The method of claim 1, where the method is configured to determine the reliability of a combinational or sequential logic circuit.

14. An electronic system comprising at least one of a plurality of gates or a plurality of storage nodes, where the plurality of gates or the plurality of storage nodes are arranged based on a process that improves a reliability of the electronic system comprising:
converting a gate-level representation of the electronic system to a graph, the graph having a vertex and an edge that correspond to nodes and gates of the electronic system;
generating input vectors, the input vectors corresponding to inputs supplied to the electronic system;
evaluating a soft error rate during a simulated operation of the electronic system; and
correlating the evaluated soft error rate to a set of parameters stored in a computer-readable medium, where the set of parameters are used to configure the nodes and the gates of the electronic system with a maximized reliability based on the evaluated soft error rate.

15. The electronic system of claim 14, where the set of parameters comprises at least one of an environmental factor, a circuit structure, or a usage model

16. The electronic system of claim 15, where the environmental factor comprises a particle flux or a probability density function of injected charge.

17. The electronic system of claim 15, where the circuit structure comprises a transistor size, a logic depth, a circuit topology, a clock speed, a gate speed, a supply voltage scaling, logic topology, or a gate circuit design.

18. The electronic system of claim 15, where the usage model comprises a plurality of input vectors.

19. The electronic system of claim 14, where converting the gate-level representation comprises processing transistor sizing information so that an equivalent inverter chain can be extracted to obtain soft error probabilities on a path of the graph.

20. The electronic system of claim 14, where the plurality of gates or the plurality of storage nodes are further arranged by processing the input vectors based on an averaging of the soft error rate associated with the input vectors.

21. The electronic system of claim 14, where the plurality of gates or the plurality of storage nodes are further arranged by determining a logical masking mechanism for the gate-level representation of the electronic system.

22. The electronic system of claim 21, where determining the logical masking mechanism comprises:
determining logic values of the vertex based on the input vectors;
for every vertex, temporarily adjusting the logic value to determine whether the logic value can propagate through the edge to an adjacent vertex; and
updating an adjacency list representation of the electronic system to emulate the logical masking mechanism.

23. The electronic system of claim 14, where the electronic system comprises a combinational logic system or a sequential logic system.

24. A computer program product for improving a reliability of an electronic system, the computer program product comprising a computer-readable medium comprising:
computer-executable code means executable to convert a gate-level representation of the electronic system to a graph, the graph having a vertex and an edge that correspond to nodes and gates of the electronic system;
computer-executable code means executable to generate input vectors, the input vectors corresponding to inputs supplied to the electronic system;
computer-executable code means executable to evaluate a soft error rate during a simulated operation of the electronic system; and
computer-executable code means executable to correlate the evaluated soft error rate to a set of parameters, where the set of parameters are used to configure the nodes and the gates of the electronic system with a maximized reliability based on the evaluated soft error rate used to configure the electronic system.

25. The computer program product of claim 24, where the computer-executable code means executable to evaluate the soft error rate comprises computer-executable code means executable to determine the soft error rate based on at least one of an environmental factor, a circuit structure, or a usage model.

26. The computer program product of claim 25, where the environmental factor comprises a particle flux or a probability density function of injected charge.

27. The computer program product of claim 25, where the circuit structure comprises a transistor size, a logic depth, a circuit topology, a clock speed, a gate speed, a supply voltage scaling, logic topology, or a gate circuit design.

28. The computer program product of claim 25, where the usage model comprises a plurality of input vectors.

29. The computer program product of claim 24, where the computer-executable code means executable to convert the gate-level representation comprises computer-executable code means executable to process transistor sizing information so that an equivalent inverter chain can be extracted to obtain soft error probabilities on a path of the graph.

30. The computer program product of claim 24, further comprising the computer-executable code means executable to process the input vectors based on an averaging of the soft error rate associated with the input vectors.

31. The computer program product of claim 24, further comprising computer-executable code means executable to determine a logical masking mechanism for the gate-level representation of the electronic system.

32. The computer program product of claim 31, where the computer-executable code means executable to determine the logical masking mechanism comprises:
computer-executable code means executable to determine logic values of the vertices based on the input vectors;
computer-executable code means executable to temporarily adjust, for every vertex, the logic value to determine whether the logic value can propagate through the edge to an adjacent vertex; and
computer-executable code means executable to update an adjacency list representation of the electronic system to emulate the logical masking mechanism.

33. The computer program product of claim 32, where the computer-executable code means executable to update the adjacency list representation comprises computer-executable code means executable to remove an element in an adjacency list that corresponds to a path between a first node and a second node if flipping the logic value at the first node does not change a logic value at the second node.

34. The computer program product of claim 24, further comprising:
computer-executable code means executable to perform a path-search process to find all paths between a determined pair of primary output bits and an internal circuit node; and
computer-executable code means executable to store a length of each path.

35. The computer program product of claim 34, where the computer-executable code means executable to perform the path-search process comprises computer-executable code means executable to perform a depth-first search (DFS) process.

36. A method for designing an electronic system with an improved reliability, the method comprising:
converting a gate-level representation of the electronic system to a graph, the graph having a vertex and an edge that correspond to nodes and gates of the electronic system, where the electronic system includes at least one of a plurality of logic gates or a plurality of storage elements;
generating input vectors, the input vectors corresponding to inputs supplied to the electronic system;
evaluating a soft error rate during a simulated operation of the electronic system;
correlating the evaluated soft error rate to a set of parameters related to the electronic system; and
arranging the at least one logic gate or the at least one storage element based on the set of parameters related to the electronic system.

37. The method of claim 36, where evaluating the soft error rate comprises determining the soft error rate based on at least one of an environmental factor, a circuit structure, or a usage model.

38. The method of claim 37, where the environmental factor comprises a particle flux or a probability density function of injected charge.

39. The method of claim 37, where the circuit structure comprises a transistor size, a logic depth, a circuit topology, a clock speed, a gate speed, a supply voltage scaling, logic topology, or a gate circuit design.

40. The method of claim 37, where the usage model comprises a plurality of input vectors.

41. The method of claim 36, where converting the gate-level representation comprises processing transistor sizing information so that an equivalent inverter chain can be extracted to obtain soft error probabilities on a path of the graph.

42. The method of claim 36, further comprising processing the input vectors based on an averaging of the soft error rate associated with the input vectors.

43. The method of claim 36, further comprising determining a logical masking mechanism for the gate-level representation of the electronic system.

44. The method of claim 43, where determining the logical masking mechanism comprises:
determining logic values of the vertices based on the input vectors;
for every vertex, temporarily adjusting the logic value to determine whether the logic value can propagate through the edge to an adjacent vertex; and
updating an adjacency list representation of the electronic system to emulate the logical masking mechanism.

45. The method of claim 44, where updating the adjacency list representation comprises removing an element in an adjacency list that corresponds to a path between a first node and a second node if flipping the logic value at the first node does not change a logic value at the second node.

46. The method of claim 36, further comprising:
performing a path-search process to find all paths between a determined pair of primary output bits and an internal circuit node; and
storing a length of each path.

47. The method of claim 36, where the set of parameters comprises at least one of a number of logic gates or a number of storage elements, a location of the at least one logic gate, a location of the at least one storage element, a logic gate speed, a logic gate fan-out, a clock speed, a supply voltage, or a length of interconnects between logic gates or storage elements.

48. The method of claim 47, where arranging the at least one logic gate or the at least one storage element comprises connecting the at least one logic gate or the at least one storage element with another logic gate or another storage element based on the set of parameters.
